(19) United States
(12) Patent Application Publication
(10) Pub. No.: US 2008/0175993 A1
(43) Pub. Date: Jul. 24, 2008

(54) REEL-TO-REEL REACTION OF A PRECURSOR FILM TO FORM SOLAR CELL ABSORBER

(76) Inventors: Jalal Ashjaee, Cupertino, CA (US); Ying Yu, Cupertino, CA (US); Bulent M. Basol, Manhattan Beach, CA (US)

Correspondence Address: PILLSBURY WINTHROP SHAW PITTMAN LLP, P.O. BOX 10500, MCLEAN, VA, 22102, US

(21) Appl. No.: 12/027,169

(22) Filed: Feb. 6, 2008

Related U.S. Application Data
(63) Continuation-in-part of application No. 11/938,679, filed on Nov. 12, 2007.
Application No. 11/938,679 is a continuation-in-part of application No. 11/549,590, filed on Oct. 13, 2006.

(51) Int. Cl. C23C 16/00

(52) U.S. Cl. 427/255.26; 118/718

(57) ABSTRACT

A roll to roll rapid thermal processing tool which is used to react a precursor material disposed over a flexible foil substrate to form a solar cell absorber. The RTP tool includes a significantly low aspect ratio process gap through which a flexible foil substrate is moved. A low temperature zone of the RTP tool forms a first portion of the process gap, a high temperature zone of the RTP tool forms a second portion of the process gap, and a buffer zone forms a third portion of the process gap that connects the first portion to the second portion of the gap. The temperature of a section of the flexible foil substrate is increased from the temperature of the low temperature zone to the temperature of the high temperature zone as the section of the continuous workpiece travels through the buffer zone. The buffer zone includes at least one low thermal conductivity section having cavities.

This application is a continuation-in-part and claims priority to U.S. patent application Ser. No. 11/938,679, filed Nov. 12, 2007 entitled “Reel-To-Reel Reaction Of Precursor Film To Form A Solar Cell Absorber” and U.S. Utility application Ser. No. 11/549,590 filed Oct. 14, 2006 entitled “Method and Apparatus For Converting Precursor Layers Into Photovoltaic Absorbers,” which applications are also expressly incorporated by reference herein.

### FIELD OF THE INVENTION

The present invention relates to method and apparatus for preparing thin films of semiconductor films for radiation detector and photovoltaic applications.

### BACKGROUND

Solar cells are photovoltaic devices that convert sunlight directly into electrical power. The most common solar cell material is silicon, which is in the form of single or polycrystalline wafers. However, the cost of electricity generated using silicon-based solar cells is higher than the cost of electricity generated by the more traditional methods. Therefore, since early 1970's there has been an effort to reduce cost of solar cells for terrestrial use. One way of reducing the cost of solar cells is to develop low-cost thin film growth techniques that can deposit solar-cell-quality absorber materials on large area substrates and to fabricate these devices using high-throughput, low-cost methods.

Group IBIIIAVIA compound semiconductors comprising some of the Group IB (Cu, Ag, Au), Group IIIA (B, Al, Ga, In, Tl) and Group VIA (O, S, Se, Te, Po) materials or elements of the periodic table are excellent absorber materials for thin film solar cell structures. Especially, compounds of Cu, In, Ga, Se and S which are generally referred to as CIGS(S), or Cu(In,Ga)(S,Se)₂ or CuIn₁₋ₓGaₓ (S_{y}Se_{1-y})ₖ, where 0≦x≦1, 0≦y≦1 and k is approximately 2, have already been employed in solar cell structures that yielded conversion efficiencies approaching 20%. Absorbers containing Group IIIA element Al and/or Group VIA element Te also showed promise. Therefore, in summary, compounds containing: i) Cu from Group IB, ii) at least one of In, Ga, and Al from Group IIIA, and iii) at least one of S, Se, and Te from Group VIA, are of great interest for solar cell applications.

The structure of a conventional Group IBIIIAVIA compound photovoltaic cell such as a Cu(In,Ga,Al)(S,Se,Te)₂ thin film solar cell is shown in FIG. 1. The device 10 is fabricated on a substrate 11, such as a sheet of glass, a sheet of metal, an insulating foil or web, or a conductive foil or web. The absorber film 12, which comprises a material in the family of Cu(In,Ga,Al)(S,Se,Te)₂, is grown over a conductive layer 13, which is previously deposited on the substrate 11 and which acts as the electrical contact to the device. The substrate 11 and the conductive layer 13 form a base 20. Various conductive layers comprising Mo, Ta, W, Ti, and stainless steel etc. have been used in the solar cell structure of FIG. 1. If the substrate itself is a properly selected conductive material, it is possible not to use a conductive layer 13, since the substrate 11 may then be used as the ohmic contact to the device. After the absorber film 12 is grown, a transparent layer 14 such as a CdS, ZnO or CdS/ZnO stack is formed on the absorber film. Radiation 15 enters the device through the transparent layer 14. Metallic grids (not shown) may also be deposited over the transparent layer 14 to reduce the effective series resistance of the device. The preferred electrical type of the absorber film 12 is p-type, and the preferred electrical type of the transparent layer 14 is n-type. However, an n-type absorber and a p-type window layer can also be utilized. The preferred device structure of FIG. 1 is called a “substrate-type” structure. A “superstrate-type” structure can also be constructed by depositing a transparent conductive layer on a transparent superstrate such as glass or transparent polymeric foil, and then depositing the Cu(In,Ga,Al)(S,Se,Te)₂ absorber film, and finally forming an ohmic contact to the device by a conductive layer. In this superstrate structure light enters the device from the transparent superstrate side. A variety of materials, deposited by a variety of methods, can be used to provide the various layers of the device shown in FIG. 1.

In a thin film solar cell employing a Group IBIIIAVIA compound absorber, the cell efficiency is a strong function of the molar ratio of IB/IIIA. If there are more than one Group IIIA materials in the composition, the relative amounts or molar ratios of these IIIA elements also affect the properties. For a Cu(In,Ga)(S,Se)₂ absorber layer, for example, the efficiency of the device is a function of the molar ratio of Cu/(In+Ga). Furthermore, some of the important parameters of the cell, such as its open circuit voltage, short circuit current and fill factor vary with the molar ratio of the IIIA elements, i.e. the Ga/(Ga+In) molar ratio. In general, for good device performance Cu/(In+Ga) molar ratio is kept at around or below 1.0. As the Ga/(Ga+In) molar ratio increases, on the other hand, the optical bandgap of the absorber layer increases and therefore the open circuit voltage of the solar cell increases while the short circuit current typically may decrease. It is important for a thin film deposition process to have the capability of controlling both the molar ratio of IB/IIIA, and the molar ratios of the Group IIIA components in the composition. It should be noted that although the chemical formula is often written as Cu(In,Ga)(S,Se)₂, a more accurate formula for the compound is Cu(In,Ga)(S,Se)ₖ, where k is typically close to 2 but may not be exactly 2. For simplicity we will continue to use the value of k as 2. It should be further noted that the notation “Cu(X,Y)” in the chemical formula means all chemical compositions of X and Y from (X=0% and Y=100%) to (X=100% and Y=0%). For example, Cu(In,Ga) means all compositions from CuIn to CuGa. Similarly, Cu(In,Ga)(S,Se)₂ means the whole family of compounds with Ga/(Ga+In) molar ratio varying from 0 to 1, and Se/(Se+S) molar ratio varying from 0 to 1.

One technique for growing Cu(In,Ga)(S,Se)₂ type compound thin films for solar cell applications is a two-stage process where metallic components of the Cu(In,Ga)(S,Se)₂ material are first deposited onto a substrate, and then reacted with S and/or Se in a high temperature annealing process. For example, for CuInSe₂ growth, thin layers of Cu and In are first deposited on a substrate and then this stacked precursor layer is reacted with Se at elevated temperature. If the reaction atmosphere also contains sulfur, then a CuIn(S,Se)₂ layer can be grown. Addition of Ga in the precursor layer, i.e. use of a Cu/In/Ga stacked film precursor, allows the growth of a Cu(In,Ga)(S,Se)₂ absorber.

Two-stage process approach may also employ stacked layers comprising Group VIA materials. For example, a Cu(In,Ga)Se₂ film may be obtained by depositing In—Ga—Se and Cu—Se layers in an In—Ga—Se/Cu—Se stack and reacting them in presence of Se. Similarly, stacks comprising Group VIA materials and metallic components may also be used. Stacks comprising Group VIA materials include, but are not limited to In—Ga—Se/Cu stack, Cu/In/Ga/Se stack, Cu/Se/In/Ga/Se stack, etc.

Selenization and/or sulfidation or sulfurization of precursor layers comprising metallic components may be carried out in various forms of Group VIA material(s). One approach involves using gases such as H₂Se, H₂S or their mixtures to react, either simultaneously or consecutively, with the precursor comprising Cu, In and/or Ga. This way a Cu(In,Ga)(S,Se)₂ film may be formed after annealing and reacting at elevated temperatures. It is possible to increase the reaction rate or reactivity by striking plasma in the reactive gas during the process of compound formation. Se vapors or S vapors from elemental sources may also be used for selenization and sulfidation. Alternately, as described before, Se and/or S may be deposited over the precursor layer comprising Cu, In and/or Ga and the stacked structure can be annealed at elevated temperatures to initiate reaction between the metallic elements or components and the Group VIA material(s) to form the Cu(In,Ga)(S,Se)₂ compound.

Reaction step in a two-stage process is typically carried out in batch furnaces. In this approach, a number of pre-cut substrates, typically glass substrates, with precursor layers deposited on them are placed into a batch furnace and reaction is carried out for periods that may range from 15 minutes to several hours. Temperature of the batch furnace is typically raised to the reaction temperature, which may be in the range of 400-600 C, after loading the substrates. The ramp rate for this temperature rise is normally lower than 5 C/sec, typically less than 1 C/sec. This slow heating process works for selenizing metallic precursors (such as precursor layers containing only Cu, In and/or Ga) using gaseous Se sources such as H₂Se or organometallic Se sources. For precursors containing solid Se, however, slow ramp rate causes Se de-wetting and morphological problems. For example, reacting a precursor layer with a structure of base/Cu/In/Se by placing it in a batch furnace with a low temperature rise rate (such as 1 C/sec) yields films that are powdery and non-uniform. Such films would not yield high efficiency solar cells.

One prior art method described in U.S. Pat. No. 5,578,503 utilizes a rapid thermal annealing (RTP) approach to react the precursor layers in a batch manner, one substrate at a time. Such RTP approaches are also disclosed in various publications (see, for example, Mooney et al., Solar Cells, vol: 30, p: 69, 1991, Gabor et al., AlP Conf. Proc. #268, PV Advanced Research & Development Project, p: 236, 1992, and Kerr et al., IEEE Photovoltaics Specialist Conf., p: 676, 2002). In the prior art RTP reactor design the temperature of the substrate with the precursor layer is raised to the reaction temperature at a high rate, typically at 10 C/sec. It is believed that such high temperature rise through the melting point of Se (220 C) avoids the problem of de-wetting and thus yields films with good morphology.

Design of the reaction chamber to carry out selenization/sulfidation processes is critical for the quality of the resulting compound film, the efficiency of the solar cells, throughput, material utilization and cost of the process. Present invention provides methods and apparatus to carry out reaction of precursor layers for CIGS(S) type absorber formation, in a roll-to-roll manner. Roll-to-roll or reel-to-reel processing increases throughput and minimizes substrate handling. Therefore, it is a preferred method for large scale manufacturing.

### SUMMARY

The present invention provides a method and integrated tool to form solar cell absorber layers on continuous flexible substrates. A roll-to-roll rapid thermal processing (RTP) tool including multiple chambers is used to react a precursor layer on a continuous flexible workpiece.

### BRIEF DESCRIPTION OF THE DRAWINGS

FIG. 1 is a cross-sectional view of a solar cell employing a Group IBIIIAVIA absorber layer;

FIG. 2 shows an apparatus to react precursor layers in a reel-to-reel fashion to form a Group IBIIIAVIA layer on a flexible foil base;

FIG. 3A shows an exemplary flexible structure comprising a flexible base and a precursor layer deposited on it;

FIG. 3B shows a base with a Group IBIIIAVIA absorber layer formed on it by reacting the precursor layer(s) of FIG. 3A;

FIG. 4 shows another apparatus to react precursor layers in a reel-to-reel fashion to form a Group IBIIIAVIA layer on a flexible foil base;

FIGS. 5A-5B show cross-sectional views of different reaction chambers with a flexible structure placed in them;

FIG. 5C shows a cross-sectional view of a reaction chamber comprising an outer chamber and an inner chamber;

FIG. 6 shows such an exemplary version of the reactor of FIG. 2;

FIG. 7A is a schematic illustration of an embodiment of a rapid thermal processing (RTP) tool of the present invention including a buffer zone connecting a cold zone to hot zone;

FIG. 7B is a graph depicting thermal profile of the RTP tool shown in FIG. 7A;

FIG. 8A is a schematic illustration of an embodiment of a roll to roll rapid thermal processing system of the present invention including an embodiment of an RTP tool;

FIG. 8B is a schematic perspective view illustration of the RTP tool shown in FIG. 8A, wherein the RTP tool includes more than one buffer zone;

FIG. 9 is a schematic illustration of another embodiment of an RTP tool of the present invention;

FIG. 10A is a schematic illustration of another embodiment of an RTP tool of the present invention;

FIG. 10B is a graph depicting thermal profile applied by a top section of the RTP tool shown in FIG. 10A; and

FIG. 10C is a graph depicting thermal profile applied by a bottom section of the RTP tool shown in FIG. 10A.

### DETAILED DESCRIPTION

Reaction of precursors, comprising Group IB material(s), Group IIIA material(s) and optionally Group VIA material(s) or components, with Group VIA material(s) may be achieved in various ways. These techniques involve heating the precursor layer to a temperature range of 350-600° C., preferably to a range of 400-575° C., in the presence of at least one of Se, S, and Te provided by sources such as; i) solid Se, S or Te sources directly deposited on the precursor, and ii) H₂Se gas, H₂S gas, H₂Te gas, Se vapors, S vapors, Te vapors etc. for periods ranging from 1 minute to several hours. The Se, S, Te vapors may be generated by heating solid sources of these materials away from the precursor also. Hydride gases such as H₂Se and H₂S may be bottled gases. Such hydride gases and short-lifetime gases such as H₂Te may also be generated in-situ, for example by electrolysis in aqueous acidic solutions of cathodes comprising S, Se and/or Te, and then provided to the reactors. Electrochemical methods to generate these hydride gases are suited for in-situ generation.

Precursor layers may be exposed to more than one Group VIA materials either simultaneously or sequentially. For example, a precursor layer comprising Cu, In, Ga, and Se may be annealed in presence of S to form Cu(In,Ga)(S,Se)₂. The precursor layer in this case may be a stacked layer comprising a metallic layer containing Cu, Ga and In and a Se layer that is deposited over the metallic layer. Alternately, Se nano-particles may be dispersed throughout the metallic layer containing Cu, In and Ga. It is also possible that the precursor layer comprises Cu, In, Ga and S and during reaction this layer is annealed in presence of Se to form a Cu(In,Ga)(S,Se)₂.

Some of the preferred embodiments of forming a Cu(In,Ga)(S,Se)₂ compound layer may be summarized as follows: i) depositing a layer of Se on a metallic precursor comprising Cu, In and Ga forming a structure and reacting the structure in gaseous S source at elevated temperature, ii) depositing a mixed layer of S and Se or a layer of S and a layer of Se on a metallic precursor comprising Cu, In and Ga forming a structure, and reacting the structure at elevated temperature in either a gaseous atmosphere free from S or Se, or in a gaseous atmosphere comprising at least one of S and Se, iii) depositing a layer of S on a metallic precursor comprising Cu, In and Ga forming a structure and reacting the structure in gaseous Se source at elevated temperature, iv) depositing a layer of Se on a metallic precursor comprising Cu, In and Ga forming a structure, and reacting the structure at elevated temperature to form a Cu(In,Ga)Se₂ layer and/or a mixed phase layer comprising selenides of Cu, In, and Ga and then reacting the Cu(In,Ga)Se₂ layer and/or the mixed phase layer with a gaseous source of S, liquid source of S or a solid source of S such as a layer of S, v) depositing a layer of S on a metallic precursor comprising Cu, In and Ga forming a structure, and reacting the structure at elevated temperature to form a Cu(In,Ga)S₂ layer and/or a mixed phase layer comprising sulfides of Cu, In, and Ga, and then reacting the Cu(In,Ga)S₂ layer and/or the mixed phase layer with a gaseous source of Se, liquid source of Se or a solid source of Se such as a layer of Se.

It should be noted that Group VIA materials are corrosive. Therefore, materials for all parts of the reactors or chambers that are exposed to Group VIA materials or material vapors at elevated temperatures should be properly selected. These parts should be made of or should be coated by substantially inert materials such as ceramics, e.g. alumina, tantalum oxide, titania, zirconia etc., glass, quartz, stainless steel, graphite, refractory metals such as Ta, refractory metal nitrides and/or carbides such as Ta-nitride and/or carbide, Ti-nitride and/or carbide, W-nitride and/or carbide, other nitrides and/or carbides such as Si-nitride and/or carbide, etc.

Reaction of precursor layers comprising Cu, In, Ga and optionally at least one Group VIA material may be carried out in a reactor that applies a process temperature to the precursor layer at a low rate. Alternately, rapid thermal processing (RTP) may be used where the temperature of the precursor is raised to the high reaction temperature at rates that are at least about 10° C./sec. Group VIA material, if included in the precursor layer, may be obtained by evaporation, sputtering, or electroplating. Alternately inks comprising Group VIA nano particles may be prepared and these inks may be deposited to form a Group VIA material layer within the precursor layer. Other liquids or solutions such as organometallic solutions comprising at least one Group VIA material may also be used. Dipping into melt or ink, spraying melt or ink, doctor-blading or ink writing techniques may be employed to deposit such layers.

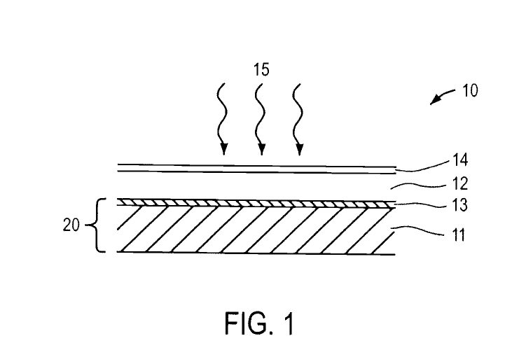

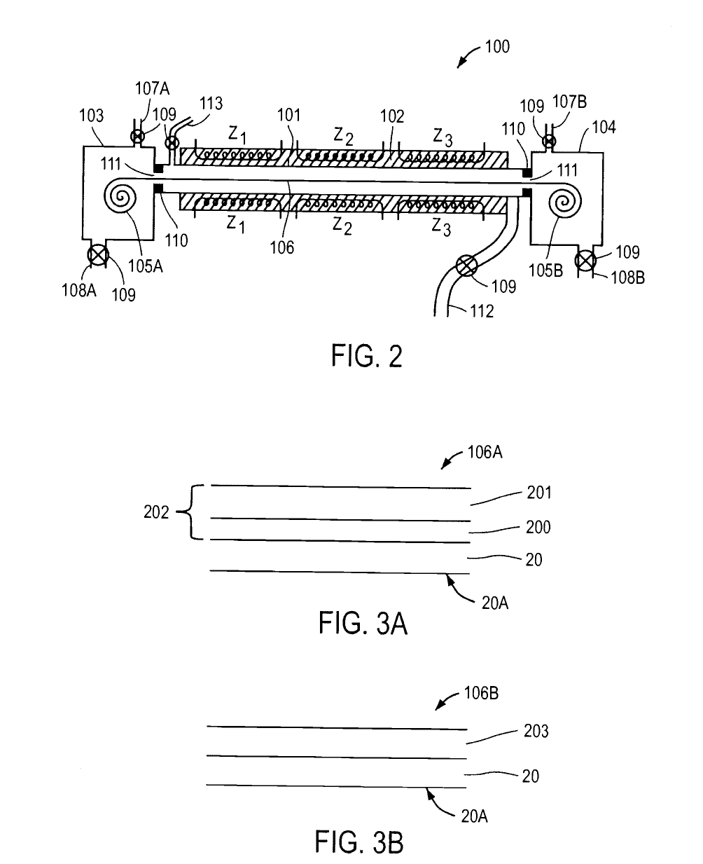

A reel-to-reel apparatus 100 or roll to roll RTP reactor to carry out reaction of a precursor layer to form a Group IBIIIAVIA compound film is shown in FIG. 2. It should be noted that the precursor layer to be reacted in this reactor may comprise at least one Group IB material and at least one Group IIIA material. For example the precursor layer may be a stack of Cu/In/Ga, Cu—Ga/In, Cu—In/Ga, Cu/In—Ga, Cu—Ga/Cu—In, Cu—Ga/Cu—In/Ga, Cu/Cu—In/Ga, or Cu—Ga/In/In—Ga etc., where the order of various material layers within the stack may be changed. Here Cu—Ga, Cu—In, In—Ga mean alloys or mixtures of Cu and Ga, alloys or mixtures of Cu and In, and alloys or mixtures of In and Ga, respectively. Alternatively, the precursor layer may also include at least one Group VIA material. There are many examples of such precursor layers. Some of these are Cu/In/Ga/Group VIA material stack, Cu-Group VIA material/In/Ga stack, In-Group VIA material/Cu-Group VIA material stack, or Ga-Group VIA material/Cu/In, where Cu-Group VIA material includes alloys, mixtures or compounds of Cu and a Group VIA material (such as Cu-selenides, Cu sulfides, etc.), In-Group VIA material includes alloys, mixtures or compounds of In and a Group VIA material (such as In-selenides, In sulfides, etc.), and Ga-Group VIA material includes alloys, mixtures or compounds of Ga and a Group VIA material (such as Ga-selenides, Ga sulfides, etc.). These precursors are deposited on a base 20 comprising a substrate 11, which may additionally comprise a conductive layer 13 as shown in FIG. 1. Other types of precursors that may be processed using the method and apparatus of the invention includes Group IBIIIAVIA material layers that may be formed on a base using low temperature approaches such as compound electroplating, electroless plating, sputtering from compound targets, ink deposition using Group IBIIIAVIA nano-particle based inks, spraying metallic nanoparticles comprising Cu, In, Ga and optionally Se, etc. These material layers are then annealed in the apparatus or reactors at temperatures in the 350-600° C. range to improve their crystalline quality, composition and density.

Annealing and/or reaction steps may be carried out in the reactors of the present invention at substantially the atmospheric pressure, at a pressure lower than the atmospheric pressure or at a pressure higher than the atmospheric pressure. Lower pressures in reactors may be achieved through use of vacuum pumps.

The reel-to-reel apparatus 100 of FIG. 2 may comprise an elongated heating chamber 101 that is surrounded by a heater system 102 which may have one or more heating zones such as Z1, Z2, and Z3 to form a temperature profile along the length of the chamber 101. In between zones there are preferably buffer regions of low thermal conductivity so that a sharp temperature profile may be obtained. Details of such use of buffer regions are discussed in U.S. application Ser. No. 11/549,590 entitled Method and Apparatus for Converting Precursor layers into Photovoltaic Absorbers, filed on Oct. 13, 2006, which is incorporated herein by reference. The chamber 101 is integrally sealably attached to a first port 103 and a second port 104. Integrally sealably means that the internal volume of chamber, the first port and the second port are sealed from air atmosphere, therefore, any gases used in the internal volume does not leak out (except at designated exhaust ports) and no air leaks into the internal volume. In other words the integration of the chamber, first and second ports are vacuum-tight. A first spool 105A and a second spool 105B are placed in the first port 103 and the second port 104, respectively, and a continuous flexible workpiece 106 or flexible structure can be moved between the first spool 105A and the second spool 105B in either direction, i.e. from left to right or from right to left. The flexible structure includes a precursor layer to be transformed into an absorber layer in the elongated chamber. The first port 103 has at least one first port gas inlet 107A and a first port vacuum line 108A. Similarly, the second port 104 has at least one second port gas inlet 107B and may have a second port vacuum line 108B. The elongated heating chamber 101 as well as the first port 103 and the second port 104 may be evacuated through either or both of the first port vacuum line 108A and the second port vacuum line 108B. The chamber 101 is also provided with at least one gas line 113 and at least one exhaust 112. There may be additional vacuum line(s) (not shown) connected to the chamber 101. Valves 109 are preferably provided on all gas inlets, gas lines, vacuum lines and exhausts so that a common chamber is formed that can be placed under a single vacuum. There are preferably slits 110 at the two ends of the chamber 101, through which the flexible structure 106 passes through. Although, evacuation of the chamber and the first and second ports is the preferred method to get rid of air from the internal volume of the tool, purging the internal volume of the tool with a gas such as N₂ through designated exhaust port(s) is also possible.

The flexible structure 106A before the reaction may be a base with a precursor film deposited on at least one face of the base. The flexible structure 106B after the reaction comprises the base and a Group IBIIIAVIA compound layer formed as a result of reaction of the precursor layer. It should be noted that we do not distinguish between the reacted and unreacted sections of the flexible structure 106 in FIG. 2, calling both the flexible structure 106. We also refer to the flexible structure as a web irrespective of whether the precursor layer over it is reacted or unreacted. The substrate of the base may be a flexible metal or polymeric foil. As described above, the precursor film on the base comprises at least Cu, In, and Ga and optionally a Group VIA material such as Se. The back side 20A of the flexible structure 106 may or may not touch a wall of the chamber 101 as it is moved through the chamber 101. The process of the present invention will now be described through specific examples.

### EXAMPLE 1

A Cu(In,Ga)(Se,S)₂ absorber layer may be formed using the single chamber reactor design of FIG. 2. An exemplary flexible structure 106A before the reaction is shown in FIG. 3A. The base 20 may be similar to the base 20 of FIG. 1. A precursor layer 200 is provided on the base 20. The precursor layer 200 comprises Cu, and at least one of In and Ga. Preferably the precursor layer 200 comprises all of Cu, In and Ga. A Se layer 201 may optionally be deposited over the precursor layer 200 forming a Se-bearing precursor layer 202. Se may also be mixed in with the precursor layer 200 (not shown) forming another version of a Se-bearing precursor layer. The flexible structure after the reaction step is shown in FIG. 3B. In this case the flexible structure 106B comprises the base 20 and the Group IBIIIAVIA compound layer 203 such as a Cu(In,Ga)(Se,S)₂ film that is obtained by reacting the precursor layer 200 or the Se-bearing precursor layer 202.

After loading the unreacted flexible structure 106A or web on, for example, the first spool 105A, one end of the web may be fed through the chamber 101, passing through the gaps 111 of the slits 110, and then wound on the second spool 105B. Doors (not shown) to the first port 103 and the second port 104 are closed and the system (including the first port 103, the second port 104 and the chamber 101) is evacuated to eliminate air. Alternately the system may be purged through the exhaust 112 with an inert gas such as N₂ coming through any or all of the gas inlets or gas lines for a period of time. After evacuating or purging, the system is filled with the inert gas and the heater system 102 may be turned on to establish a temperature profile along the length of the chamber 101. When the desired temperature profile is established, the reactor is ready for process.

During the process of forming, for example, a Cu(In,Ga)Se₂ absorber layer, a gas comprising Se vapor or a source of Se such as H₂Se may be introduced into the chamber, preferably through chamber gas inlet 113. The exhaust 112 may now be opened by opening its valve so that Se bearing gas can be directed to a scrubber or trap (not shown). It should be noted that Se is a volatile material and at around the typical reaction temperatures of 400-600 C its vapor tends to go on any cold surface present and deposit in the form of solid or liquid Se. This means that, unless precautions taken during the reaction process, Se vapors may pass into the first port 103 and/or the second port 104 and deposit on all the surfaces there including the unreacted portion of the web in the first port 103 and the already reacted portion of the web in the second port 104. To minimize or eliminate such Se deposition, it is preferable to introduce a gas into the first port 103 through first port gas inlet 107A and introduce a gas into the second port 104 through the second port gas inlet 107B. The introduced gas may be a Se-bearing and/or S-bearing gas that does not breakdown into Se and/or S at low temperature, but preferably the introduced gas is an inert gas such as N₂ and it pressurizes the two ports establishing a flow of inert gas from the ports towards the chamber 101 through the gaps 111 of the slits 110.

The velocity of this gas flow can be made high by reducing the gaps 111 of the slits 110 and/or increasing the flow rate of the gas into the ports. This way diffusion of Se vapor into the ports is reduced or prevented, directing such vapors to the exhaust 112 where it can be trapped away from the processed web. The preferred values for the gap 111 of the slits 110 may be in the range of 0.5-5 mm, more preferably in the range of 1-3 mm. Flow rate of the gas into the ports may be adjusted depending on the width of the slits which in turn depends on the width of the flexible structure 106 or web. Typical web widths may be in the range of 1-4 ft.

Once the Se-bearing gas and inert gas flows are set and the desired temperature profile of the chamber 101 is reached, the flexible structure 106 may be moved from the first port 103 to the second port 104 at a pre-determined speed. This way, an unreacted portion of the flexible structure 106 comes off the first roll 105A, enters the chamber 101, passes through the chamber 101, gets reacted forming a Cu(In,Ga)Se₂ absorber layer on the base of the web and gets rolled onto the second spool 105B in the second port 104. It should be noted that there may be an optional cooling zone (not shown) within the second port 104 to cool the reacted web before winding it on the second spool 105B.

The above discussion is also applicable to the formation of absorber layers containing S. For example, to form a Cu(In,Ga)S₂ layer the Se-bearing gas of the above discussion may be replaced with a S-bearing gas such as H₂S. To form a Cu(In,Ga)(Se,S)₂, a mixture of Se-bearing gas and S-bearing gas may be used. Alternately, a Se-bearing precursor may be utilized and reaction may be carried out in a S-bearing gas.

One feature of the system 100 of FIG. 2 is that the flexible structure 106 may be moved from left to right as well as from right to left. This way more than one reaction step may be carried out. For example, a first reaction may be carried out as the web is moved from left to right, then a second reaction may be carried out as the web is moved from right to left and the reacted web may be unloaded from the first spool 105A. Of course even more steps of reaction or annealing etc., may be carried out by moving the web more times between the first spool 105A and the second spool 105B. Reaction conditions, such as gas flow rates and the reaction temperature may be different for the various reaction steps. For example, the temperature profile of the chamber 101 may be set to a maximum temperature of 400° C. for the first reaction step when the web is moved from left to right. This way the precursor of the web may be partially or fully reacted or annealed at 400 C.

After substantially all portions of the web is rolled on the second spool 105B, the maximum temperature of the temperature profile may be adjusted to a higher value, such as to 550° C., and the web may be moved from right to left as the already annealed or reacted precursor layer may be further reacted, annealed or crystallized, this time at the higher temperature of 550° C. It should be noted that a similar process may be achieved by making the chamber 101 longer and setting a temperature profile along the chamber 101 such that as the web travels from left to right, for example, it travels through a zone at 400° C. and then through a zone at 550° C. However, using bi-directional motion as described above, the length of the chamber 101 may be reduced and still the two step/two temperature reaction may be achieved. To keep the temperature of the web high when it is rolled onto either one of the first spool 105A or the second spool 105B in between reaction steps, there may be optional heaters (not shown) placed in either or both of the first port 103 and the second port 104.

It should be noted that in addition to the reactor temperature and the web speed, the reaction gas composition may also be changed in the multi-step reaction approach described above. For example, during the first reaction step when the web is moved from left to right a first gas such as H₂Se may be used in the chamber 101 to form a selenized precursor layer. During the second reaction step when the web is moved from right to left, on the other hand, another gas such as H₂S may be introduced in the chamber 101. As a result, the selenized precursor layer may be reacted with S as the web is moved from the second spool 105B to the first spool 105A and thus a Cu(In,Ga)(Se,S)₂ layer may be grown by converting the already selenized precursor layer into sulfo-selenide. Selecting the gas concentrations, web speeds and reaction temperatures the amount of Se and S in the absorber layer may be controlled. For example, S/(Se+S) molar ratio in the final absorber layer may be increased by increasing the web speed and/or reducing the reaction temperature during the first process step when reaction with Se is carried out. Similarly, the S/(Se+S) molar ratio may also be increased by reducing the web speed and/or increasing the reaction temperature during the second step of reaction where reaction with S is carried out. This provides a large degree of flexibility to optimize the absorber layer composition by optimizing the two reaction steps independent from each other.

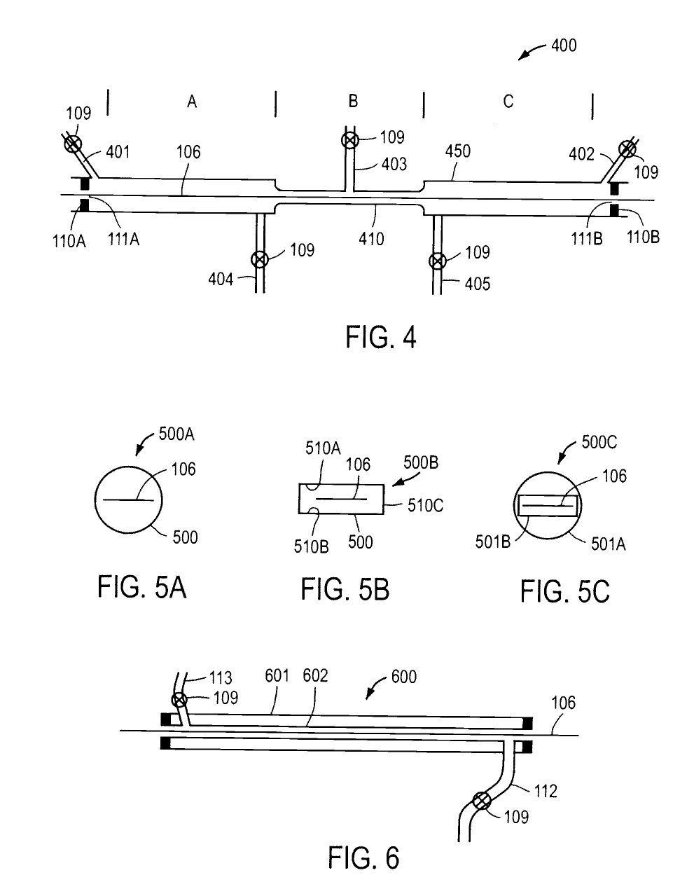

Another embodiment of the present invention is shown in FIG. 4. The reactor system 400 in FIG. 4 comprises a three-section chamber 450 which is an example of a more general multi-chamber design. The three-section chamber 450 of FIG. 4 comprises sections A, B and C. Heating means around each section as well as the first port, the first spool, the second port and the second spool are not shown in this figure to simplify the drawing. However, designs similar to those shown in FIG. 2 may be used for such missing parts. The heating means may be heat lamps, heater coils etc. and they may have independent controls to yield different temperature values and profiles in the sections of A, B and C.

Important feature of the design of FIG. 4 is that sections A and C are separated by a segment, preferably a low-volume segment 410 which is within section B of the three-section chamber 450. There are means to bring gas into each of the sections A, B and C. For example, inlets 401 and 402 may bring gas into sections A and C, respectively, whereas inlet 403 may bring gas into the low-volume segment 410 in section B. Exhausts 404 and 405 may be provided to exhaust gases from sections A and C, respectively. A flexible structure 106 to be processed or reacted may pass through a first gap 111A of a first slit 110A, enter the three-section chamber 450 and then exit through the second gap 111B of a second slit 110B.

### EXAMPLE 2

A Cu(In,Ga)(Se,S)₂ absorber layer may be formed using the three-section chamber reactor of FIG. 4. After loading the unreacted flexible structure 106, pumping and purging the system as described in Example 1, the process may be initiated. Sections A, B and C of the three-section chamber 450 may have temperatures of T1, T2 and T3 which may or not be equal to each other. Furthermore, each of the sections A, B and C may have a temperature profile rather than just a constant temperature along their respective lengths. During processing, a first process gas such as N₂ may be introduced into the low-volume segment 410 in section B through inlet 403, while a second process gas and a third process gas may be introduced in sections A and C, respectively, through inlets 401 and 402, respectively.

The second process gas and the third process gas may be the same gas or two different gases. For example, the second process gas may comprise Se and the third process gas may comprise S. This way when a portion on the flexible structure 106 enters the section A of the three-section chamber 450 through the first gap 111A of the first slit 110A, the precursor layer on the portion starts reacting with Se forming a selenized precursor layer on the portion. When portion enters the low-volume segment 410, it gets annealed in the N₂ gas (if section B is heated) within this segment until it enters section C. In section C sulfidation or sulfurization takes place due to presence of gaseous S species, and a Cu(In,Ga)(Se,S)₂ absorber layer is thus formed on the portion before the portion exits the three-section chamber 450 through the second gap 111B of the second slit 110B. The S/(Se+S) molar ratio in the absorber layer may be controlled by the relative temperatures and lengths of the sections A and C. For example, at a given web speed the S/(Se+S) ratio may be increased by decreasing the length and/or reducing the temperature of section A.

Alternately, or in addition, the length and/or the temperature of section C may be increased. Reverse may be done to reduce the S/(Se+S) molar ratio. It should be noted that, as in the previous example, it is possible to run the flexible structure or web backwards from right to left to continue reactions. It is also possible to change the gases introduced in each section A, B and C of the three-section chamber 450 to obtain absorber layers with different composition. The design of FIG. 4 has a unique feature of allowing two different gases or vapors to be present in two different sections of the reactor so that reel-to-reel continuous processing may be done on a web substrate by applying different reaction temperatures and different reaction gases in a sequential manner to each portion of the web. Introducing an inert gas to a reduced volume segment in between the two sections (sections A and C in FIG. 4) acts as a diffusion barrier and minimizes or eliminates intermixing between the different gases utilized in those two sections. The first gas introduced through inlet 403 in FIG. 4 flows through the low-volume segment 410 to the right and to the left opposing any gas flows from sections A and C towards each other. It should be noted that more sections may be added to the reactor design of FIG. 4 with more low-volume segments between them and each section may run with different temperature and gas to provide process flexibility for the formation of high quality Group IBIIIAVIA compound absorber layers. Also more gas inlets and/or exhaust may be added to the system of FIG. 4 and locations of these gas inlets and exhaust may be changed.

A variety of different cross sectional shapes may be used for the chambers of the present invention. Two such chambers 500A and 500B having circular and rectangular cross sections, respectively, are shown in FIGS. 5A and 5B. Substantially cylindrical reaction chambers with circular cross section are good for pulling vacuum in the chamber even if the chamber is made from a material such as glass or quartz. The circular chambers however, get very large as the substrate or web width increases to 1 ft, 2 ft or beyond. Temperature profiles with sharp temperature changes cannot be sustained using such large cylindrical chambers and thus roll-to-roll RTP process cannot be carried out on wide flexible substrates such as substrates that may be 1-4 ft wide or even wider.

As shown in FIG. 5B, the chamber 500B includes a rectangular gap defined by the top wall 510A, bottom wall 510B, and the side walls 510C. In this case the chamber is preferably constructed of metal because for pulling vacuum in such a chamber without breaking it requires very thick walls (half an inch and larger) if the chamber is constructed of quartz or glass. In this configuration, the top wall 510A and the bottom wall 510B are substantially parallel to each other, and the flexible structure 106 is placed between them. Chambers with rectangular cross section or configuration is better for reducing reactive gas consumption since the height of such chambers may be reduced to below 10 mm, the width being approximately close to the width of the flexible structure (which may be 1-4 ft). Such small height also allows reaction in Group VIA vapor without the need to introduce too much Group VIA material into the chamber. It should be noted that the height of the chamber 500B, i.e., gap size, is the distance between the top and the bottom walls and small gap size is necessary to keep a high overpressure of Group VIA material over the surface of the precursor layer during reaction. Also these chambers can hold sharply changing temperature profiles even for flexible substrate widths beyond 4 ft. For example, a temperature profile along the length of a chamber with a rectangular cross-section may comprise a temperature change of 400-500 C within a distance of a few centimeters. Such chambers, therefore, may be used in roll-to-roll RTP mode wherein a section of a precursor film on a substrate traveling at a speed of a few centimeters per second through the above mentioned temperature change experiences a temperature rise rate of 400-500 C/sec. Even higher rates of a few thousand degrees C. per second may be achieved by increasing the speed of the substrate.

As shown in cross sectional view in FIG. 5C, another preferred chamber design includes a dual chamber 500C where an inner chamber 501B with rectangular cross section is placed within a cylindrical outer chamber 501A with circular cross section. In this case the flexible structure 106 or web passes through the inner chamber 501B which may be orthorhombic in shape and all the gas flows are preferably directed to and through the inner chamber 501B which has a much smaller volume than the outer chamber 501A. This way waste of reaction gases is minimized but at the same time the whole chamber may be easily evacuated because of the cylindrical shape of the outer chamber 501B, even though the chamber may be made out of a material such as quartz. Heaters (not shown) in this case may be placed outside the inner chamber 501B, but inside the outer chamber 501A. This way sharp temperature profiles can be sustained along the length of the rectangular cross section chamber while having the capability to evacuate the reactor body.

FIG. 6 shows such an exemplary version of the reactor of FIG. 2. Only the chamber portion is shown for simplifying the drawing. As can be seen from this figure, the dual-chamber 600 comprises a cylindrical chamber 601 and an orthorhombic chamber 602 which is placed in the cylindrical chamber 601. Gas inlet 113 and exhaust 112 are connected to the orthorhombic chamber 602. It should be noted that the cylindrical chamber 601 may not be hermetically sealed from the orthorhombic chamber so that when the overall chamber is pumped down, pressure equilibrates between the cylindrical chamber 601 and the orthorhombic chamber. Otherwise, if these chambers are sealed from each other, they may have to be pumped down together at the same time so that there is not a large pressure differential between them.

Solar cells may be fabricated on the compound layers formed in the reactors of the present invention using materials and methods well known in the field. For example a thin (<0.1 microns) CdS layer may be deposited on the surface of the compound layer using the chemical dip method. A transparent window of ZnO may be deposited over the CdS layer using MOCVD or sputtering techniques. A metallic finger pattern is optionally deposited over the ZnO to complete the solar cell.

In the following, various embodiments of roll-to-roll or reel-to-reel RTP tools will be provided. The RTP tool of the present invention may have at least one cold zone, at least one hot zone and a buffer zone connecting these two zones. The zones in this embodiment are formed along a process gap of the RTP tool. A workpiece is processed in the process gap while it is moved in a process direction. It is understood that the terms “hot” or “warm” or “high temperature” zone and “cold” or “cool” or “low temperature” zone are intended as being conditionally relative, such that the hot/warm/high temperature zone is warmer than the cold/cool/low temperature zone, though the degree of differential does not require a maximum low temperature for the cold zone or a minimum high temperature for the hot zone.

In one embodiment, the zones are preferably placed along the process gap and form a section surrounding a portion of the process gap so that when a portion of the workpiece is advanced through a specific zone, that portion of the workpiece is treated with the thermal conditions that are assigned to that zone. In accordance with the principles of the present invention, buffer zones may be formed as part of a processing gap of the RTP tool and connect two zones which are kept in different temperatures. In this respect, a buffer zone may connect a lower temperature zone to a higher temperature zone, or a higher temperature zone to a lower temperature zone. For example, the low temperature zone may be kept at a first temperature so that a portion of a continuous workpiece is subjected to the first temperature as the portion of the continuous workpiece travels through the low temperature zone. The high temperature zone, on the other hand, may be kept at a second temperature so that the portion of the continuous workpiece is subjected to the second temperature when it travels through the high temperature zone. If the buffer zone connects the lower temperature zone to the higher temperature zone and if the portion of the continuous workpiece is made to travel from the lower temperature zone to the higher temperature zone, the temperature of the portion of the continuous workpiece is increased from the first temperature to the second temperature as it travels through the buffer zone. This, in effect, provides conditions of rapid thermal processing to the portion of the continuous workpiece. The continuous workpiece is moved at a predetermined speed through the buffer zone from the low temperature to high temperature zones of the thermal processing tool zone such that the rate of heating experienced by a portion of the continuous workpiece as it travels through the buffer zone can be easily made 10° C./second or much higher (such as 100-500 C/sec) by selecting the values for the low temperature, the high temperature, the speed of the continuous workpiece and the length of the buffer zone. In a particular embodiment, the buffer zone is less than 10% of the length of the high temperature zone, and in a preferred embodiment the length of the buffer zone is in the range of 1-5% of the length of the high temperature zone. In preferred embodiments, the specific length of the first buffer zone is less than 10 cm, and preferably less than 5 cm. This flexibility and the ability to reach very high temperature rates at low cost, keeping the processing throughputs very high are unique features of the present design.

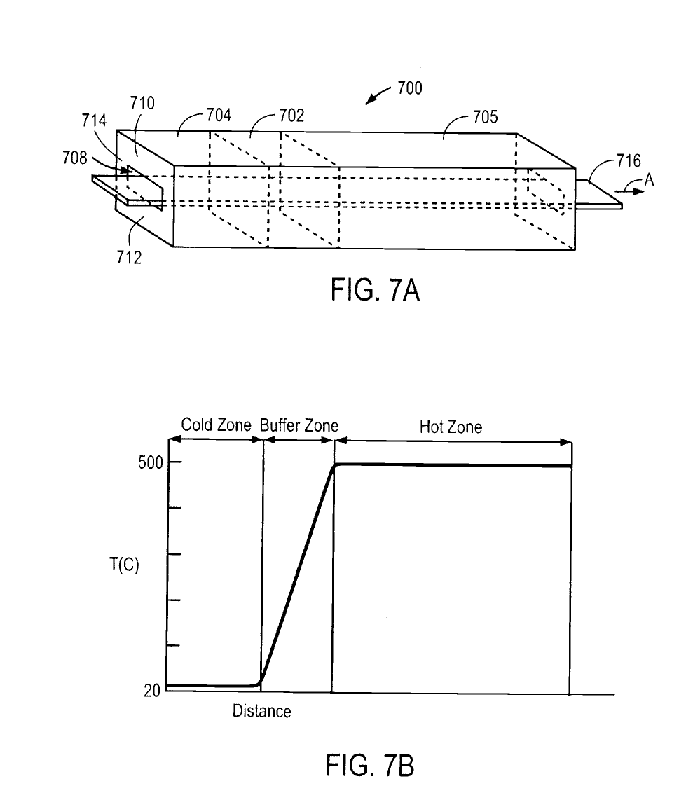

FIG. 7A shows a section of an exemplary rapid thermal processing system 700 having a buffer zone 702 connecting a low temperature zone 704 such as a cold zone to a high temperature zone 706 or a hot zone. The system 700 may be a part of a larger system including more zones. For example, the hot zone 706 may be followed by another buffer zone and cold zone combination. Furthermore, the hot zone may be divided by one or more buffer zones to establish a desired temperature profile within the hot zone, each heated zone having a different temperature. A process gap 708 of the system is defined by a top wall 710, a bottom wall 712 and side walls 714. The process gap 708 extends through the cold zone 704, the buffer zone 702, and the hot zone 706. In each zone, the top wall, the bottom wall, and side walls may be made of the same material or different materials, and using different construction features. The gap height and width may be varied along the process gap in each zone. The process gap is preferably in the range of 2 mm-20 mm height and 10-200 cm width. An aspect ratio for the gap may be between 1:50 and 1:1000. The aspect ratio is defined herein as the ratio between height (or depth) of the gap and its smallest lateral dimension (width). The height of the process gap may be increased to larger values such as up to about 50 mm if the speed of the continuous workpiece is increased, and therefore the length of the buffer zone may also be increased still keeping the temperature rise rates at or above 10 C/sec.

A continuous workpiece 716 is moved with a predetermined speed in the process gap 708 during the process, in the direction depicted by arrow A. In this embodiment, a cooling system (not shown) may be used to maintain low temperature in cold zone 704, and a heating system (not shown) is used to maintain high temperature in the hot zone 706. As will be described more fully below, the buffer zone 702 is a low thermal conductivity zone connecting the cold zone to hot zone so that both zones are maintained in their set temperature ranges without any change by using a short buffer zone. It should be noted that the shorter the buffer zone is, the higher the temperature rise rate can be experienced by a portion of a workpiece moving at a constant speed through the buffer zone. In that respect, the present invention achieves buffer zone lengths in the range of 2-15 cm, making it possible to keep one end of the buffer zone at room temperature (about 20° C.) and the other end at a high temperature in the range of 500-600° C. The low thermal conductivity characteristics of the buffer zone may be provided by constructing at least one of the top wall, bottom wall and optionally side wall of the buffer zone, or at least a portion of them with low thermal conductivity materials and/or features.

As shown in FIG. 7B, in an exemplary temperature profile for the system 700, the low thermal conductivity characteristics of the buffer zone of the system 700 steps up the temperature of the continuous workpiece, in a sharp manner, from a colder to a hotter temperature. This way as the workpiece is moved from a cold zone to a hot zone it experiences a temperature rise rate determined by its speed. The temperature of the cold zone may be less than 50° C., preferably 20-25° C., and temperature of the hot zone may be 300-600° C., preferably 500-550° C. If the length of the buffer zone is 10 cm, and if the continuous workpiece is moved at a speed of 1 cm/second, the rate of heating of the workpiece in the buffer zone will be about (550-20)/10=53° C./sec in this example. A temperature controller, not shown, can be used to control the heating of the cold zone and the hot zone. This approximation of temperature rise is valid as long as heat conduction to the substrate in the hot and cold zone is not a limiting factor.

As shown in FIG. 7A each zone comprises and surrounds a predetermined portion of the process gap 708, and the workpiece portion in them is exposed to the exemplary thermal profile shown in FIG. 7B. Within this context, ‘portion’ of the continuous workpiece may be defined as a rectangular portion of the workpiece having a length, width and thickness, wherein the width and the thickness are the width and thickness of the continuous flexible workpiece. For example, if a portion of the continuous flexible workpiece is in the hot zone, substantially all of that portion of the continuous workpiece material is exposed to the temperature of the hot zone. The same is true for cold and buffer zones. The portion of the continuous workpiece in these zones will be exposed to the conditions of these zones.

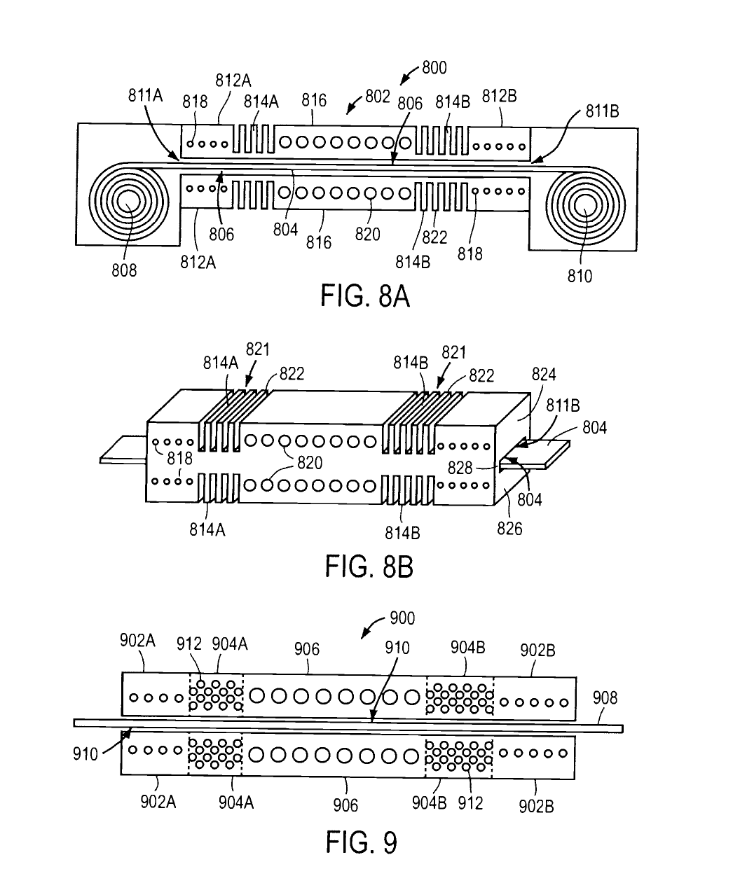

FIG. 8A shows a roll to roll processing system 800 including an embodiment of a RTP tool 802 to process a flexible continuous workpiece 804 (workpiece hereinafter). The workpiece 804 is extended along a process gap 806 of the RTP tool 802, and between a supply spool 808 and a receiving spool 810. FIG. 8B illustrates the RTP tool in side-perspective view. Referring to FIGS. 8A and 8B, the process gap 806 extends between an entry opening 811A and an exit opening 811B, and defined by a top wall 824, a bottom wall 826 and side walls 828. A moving mechanism (not shown) unwraps and feeds the workpiece 804 into the process gap 806, and takes up and wraps the workpiece 804 around the receiving spool 810 when it leaves the process gap 806. It should be noted that one important feature of the present design is its leak-free construction. Air and/or oxygen is preferably not allowed to enter the process gap. This requires the process gap to be preferably constructed in a leak-free manner and vacuum can be pulled in the process gap to eliminate air before the RTP process is initiated, preferably after filling back the process gap with an inert gas or a reactive gas such as a gas comprising Se and or S.

In this embodiment, the RTP tool includes a first cold zone 812A, a first buffer zone 814A, a hot zone 816, a second buffer zone 814B, and a second cold zone 812B. Accordingly, the first buffer zone 814A facilitates heating of the workpiece 804, and the second buffer zone 814B cooling of the workpiece 804. The second buffer zone 814B connects the hot zone, which is kept in a high temperature, to the cold zone, which is kept in a lower temperature. In this embodiment, in order to cause a slower rate of cooling, the second buffer zone 814B may be longer than the first buffer zone 814A which may be kept short to facilitate rapid heating of the workpiece. A cooling system with cooling members 818 cools the cold zones 812A and 812B. An exemplary cooling system may be a cooling system using a fluid coolant such as a gas or liquid coolant. The hot zone 816 includes a series of heating members 820 placed along the hot zone 816. Heating members each may be controlled separately or in groups through use of temperature controllers and thermocouples placed near the heating members in each zone. In that respect it is possible to separate the hot zone in multiple heated zones with one or more heaters that are controlled separately. In this embodiment, the buffer zones 814A and 814B include low thermal conductivity features 821 to reduce flow of heat from the hot zone towards the cool zones.

Details of buffer zones will be described using FIG. 8B which shows the buffer zone 814A of the RTP tool 802 in more detail. Thermal conductivity of at least a portion of the buffer zone 814A may be lowered by forming cavities within the walls of the buffer zone without negatively impacting the mechanical integrity of the walls. This is important since, as explained before, the process gap needs to be leak-free. The cavities may extend perpendicular to the lateral axis of the process gap by forming grooves in the walls. Alternatively, as described in another embodiment below (see FIG. 9), the cavities may be through cavities (or holes) formed through the width of the top wall or bottom wall portions and height of the side walls. By cutting grooves into or onto the top and bottom walls, the cross sectional area of the wall material (which may be, for example, stainless steel) interconnecting the hot and cold zones is reduced. This way thermal conduction through this cut region is reduced. In this embodiment, both the top wall and the bottom wall of the buffer zones include an equal number of cuts placed in a symmetrical manner. To form the buffer zone, the cuts on the top and the bottom extend along the same portion of the process gap 806. Although in this embodiment, side walls 828A may not include any of the features 822, it is possible to have features on the side walls as well. The cuts in the top and bottom walls may each have a width of 1 mm or greater. Their depth may be about 50-80% of the thickness of the top wall or the bottom wall. It should be noted that use of this design with cuts yield the desirable near-linear temperature change going from a hot zone to a cold zone or vice-versa as shown in FIG. 7B. In one embodiment, the hot zone and the buffer zone may be enclosed in a thermal insulator to avoid heat loss from the reactor. Alternately, the RTP tool 802 may be fully covered by an insulating enclosure to protect users from high temperature and to reduce heat loss.

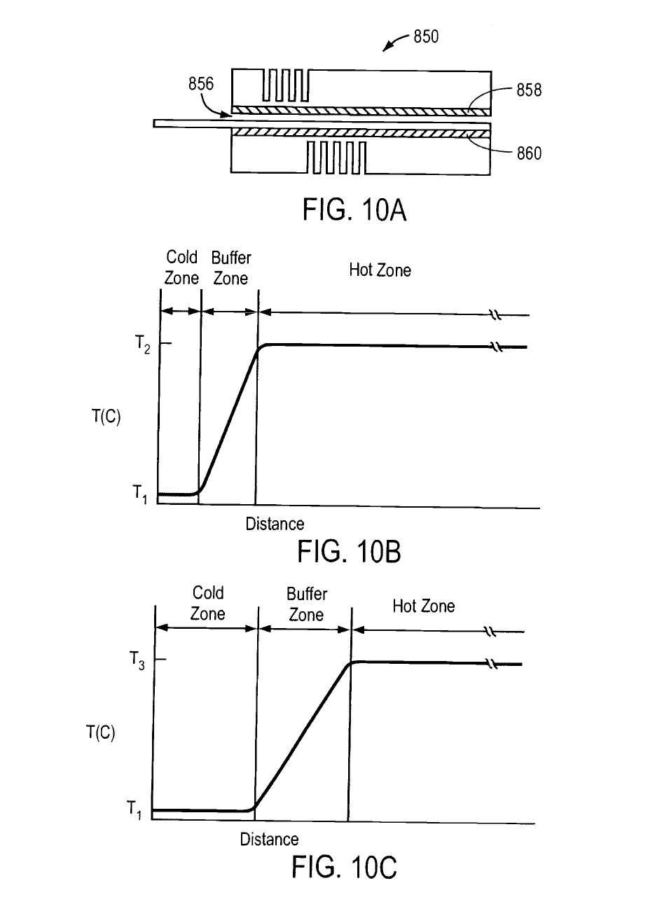

FIG. 9 shows another embodiment of an RTP tool 900 having cold zones 902A and 9002B, buffer zones 904A and 904B, and hot zone 906. A continuous workpiece 908 is extended through a process gap 910 of the tool 900. Design of cold and hot zones are the same as the RTP tool 802 described in the previous embodiment. In this embodiment, low thermal conductivity features in the buffer zones may be holes 912 which are drilled within the walls of the buffer zones 904A and 904B. Presence of the holes 912 reduces the cross sectional area of the metallic wall material conducting the heat from the hot zone to the cold zones, replacing this material with air. It should be noted that in FIGS. 7A and 8A, the workpiece is shown in the middle of the process gap. However, depending on the position of the process gap (horizontal, vertical or at an angle) one face of the workpiece may actually touch at least one of the walls defining the process gap. In FIG. 10A we show a situation where the bottom of the workpiece touches the bottom wall.

FIG. 10A shows a RTP tool 850 in side partial view. The RTP tool 850 is an alternative embodiment of the RTP tool 802 shown in FIGS. 8A and 8B. In this embodiment, different thermal profiles are established at the upper and lower walls of the process gap by having buffer regions associated with the top and bottom walls that are disposed between hot regions and cold regions, such that the top buffer region is not necessarily co-extensive with the bottom buffer region, and in fact the bottom buffer region may overlap either or both of the top cold region and the top hot region, and vice versa. For example, the temperature profile of the upper wall may be as shown in FIG. 10B and the temperature profile of the lower wall may be as shown in FIG. 10C. The benefit of this design is the fact that the workpiece may be thermally coupled to one of the walls (lower wall in FIG. 10A) and therefore experiences substantially the thermal profile of that wall (FIG. 10C), whereas the opposite wall of the reaction chamber may be at a different temperature (FIG. 10B). By keeping the top wall hot region hotter than a bottom wall cold region disposed directly below it, for example, it is possible to thermally activate the gaseous species (such as Se vapors or H₂Se vapors etc.) which may be present in the process gap while controlling the temperature of the workpiece itself by the bottom wall hot region. Having a top hot wall region across from the workpiece surface also keeps reactive species in vapor phase by not letting them condense and possibly drip down on the workpiece surface. For example, by maintaining a top hot wall region, Se condensation may be avoided during a RTP process that uses Se species to selenize precursors comprising Cu, In and Ga. Different temperature profiles at different regions of the top and bottom walls of the process gap may also be obtained by using upper wall insert 858 and lower wall insert 860 which may have different designs and thermal conductivities. For example, if an upper wall insert 858 is well thermally coupled to a hot region but poorly thermally coupled to a cold region, then it is possible to move the high temperatures closer to the inlet 856 along the upper wall insert 858.

Although the present invention is described with respect to certain preferred embodiments, modifications thereto will be apparent to those skilled in the art.

We claim:

1. An apparatus used to react precursor material disposed over a continuous workpiece that continuously feeds portions thereof through the apparatus to form a solar cell absorber, comprising:
a rapid thermal processing tool including a continuous and leak-free process gap through which the continuous workpiece travels, the process gap including:
a top wall and a bottom wall such that there exists an aspect ratio of 1/50 to 1/1000, wherein the top wall and the bottom wall are partitioned into two different temperature zones separated by a first buffer zone therebetween, wherein the first buffer zone includes a plurality of cavities within at least one of the top wall and the bottom wall that provide low thermal conductivity areas that together significantly inhibit transfer of thermal energy to the adjacent two different temperature zones while still maintaining the process gap, including the buffer zone, leak-free.

2. The apparatus of claim 1 wherein:
the two different temperature zones include:
a first zone maintained at substantially a first temperature range so that a section of the continuous workpiece is subjected to the first temperature range as the section of the continuous workpiece travels through the first zone; and
a second zone maintained at substantially a second temperature range so that the section of the continuous workpiece is subjected to the second temperature range as the section of the continuous workpiece travels through the second zone, wherein the second temperature range is higher than the first temperature range.

3. The apparatus of claim 2, wherein each of the top wall and the bottom wall include the plurality of cavities that provide low thermal conductivity areas that together significantly inhibit transfer of thermal energy to the adjacent two different temperature zones.

4. The apparatus of claim 3 further including a moving mechanism to move the portions of the continuous workpiece through the first and second zones, and the first buffer zone at a predetermined speed, wherein at the predetermined speed a heating rate on that portion of the continuous workpiece within the first buffer zone is at least 10° C./second.

5. The apparatus of claim 4, wherein a length of the first buffer zone is less than 10% of the length of the second process zone.

6. The apparatus of claim 5, wherein the length of the first buffer zone is in the range of 1-5% of the length of the second zone.

7. The apparatus of claim 6, wherein the length of the first buffer zone is less than 10 cm.

8. The apparatus of claim 6, wherein the length of the first buffer zone is less than 5 cm.

9. The apparatus of claim 4 further including a temperature controller that maintains a temperature differential between the first process zone and the second process zone of at least 300° C.

10. The apparatus of claim 4, wherein the cavities are holes within each of the top wall and the bottom wall.

11. The apparatus of claim 10 wherein the holes are substantially cylindrical.

12. The apparatus of claim 4, wherein the cavities are slits disposed in a direction that is substantially perpendicular to a direction of travel of the continuous workpiece.

13. The apparatus of claim 12, wherein a width of each slit is at least 1 mm.

14. The apparatus of claim 13, wherein a depth of each slit is 50% to 80% of a thickness of the top wall and the bottom wall.

15. The apparatus of claim 4 further comprising a third zone that is maintained at a third temperature range and a second buffer zone disposed between the second zone and the third zone, wherein the second buffer zone includes a further plurality of cavities within each of the top wall and the bottom wall that provide further low thermal conductivity areas that together significantly inhibit transfer of thermal energy between the second zone and the third zone while still maintaining the process gap, including the second buffer zone, leak-free, and wherein the moving mechanism continuously moves the continuous workpiece at the predetermined speed through the first, second, and third zones and the first and second buffer zones.

16. The apparatus of claim 15, wherein a length of the second buffer zone is less than 10% of the length of the second process zone.

17. The apparatus of claim 16, wherein the length of the first buffer zone and the second buffer zone is less than 10 cm.

18. The apparatus of claim 16, wherein the length of the first buffer zone and the second buffer zone is less than 5 cm.

19. The apparatus of claim 3, wherein a length of the first buffer zone is less than 10% of the length of the second process zone.

20. The apparatus of claim 19, wherein the length of the first buffer zone is in the range of 1-5% of the length of the second zone.

21. The apparatus of claim 20, wherein the length of the first buffer zone is less than 10 cm.

22. The apparatus of claim 20, wherein the length of the first buffer zone is less than 5 cm.

23. The apparatus of claim 3 further including a temperature controller that maintains a temperature differential between the first process zone and the second process zone of at least 300° C.

24. A method of reacting precursor material disposed over a continuous workpiece, the continuous workpiece being formed in a sheet that is continuously fed comprising:
feeding at a predetermined rate range a substantial length of the sheet of the continuous workpiece through a process gap that is leak-free;
heating each portion of the substantial length of the sheet of the continuous workpiece in a first zone of the process gap maintained at substantially a first temperature range;
heating each portion of the substantial length of the sheet of the continuous workpiece in a second zone of the process gap maintained at substantially a second temperature range, wherein the second temperature range is higher than the first temperature range; and
passing each portion of the substantial length of the sheet of the continuous workpiece through a first buffer zone of the process gap that connects the first zone to the second zone, wherein the predetermined rate range causes each portion of the substantial length to be disposed within the first buffer zone for a period that is less than 10% of another period that each portion is disposed within the second zone, wherein the buffer zone includes cavities of low thermal conductivity that together significantly inhibit transfer of thermal energy from the second zone to the first zone while still maintaining the process gap, including the buffer zone, leak-free.

25. The method according to claim 24 wherein the step of passing each portion of the substantial length of the sheet of the continuous workpiece through the first buffer zone causes a heating rate on that portion that is more than 10° C./second within the first buffer zone.

26. The method according to claim 25 wherein the difference between the first temperature range and the second temperature range is at least 300° C.

27. The method according to claim 25 further comprising the steps of:
processing each portion of the substantial length of the sheet of the continuous workpiece in a third zone of the process gap maintained at substantially a third temperature range; and
passing each portion of the substantial length of the sheet of the continuous workpiece through a second buffer zone of the process gap that connects the second zone to the third zone, wherein the predetermined rate range causes each portion of the substantial length to be disposed within the second buffer zone for a period that is less than 10% of another period that each portion is disposed within the second zone, wherein the second buffer zone includes cavities of low thermal conductivity that together significantly inhibit transfer of thermal energy between the second zone and the third zone while still maintaining the process gap, including the second buffer zone, leak-free.

28. An apparatus used to continuously feed portions of a continuous workpiece with a front surface and a back surface through the apparatus to react a precursor layer disposed over the front surface of the continuous workpiece to form a solar cell absorber, comprising:
a rapid thermal processing tool, the rapid thermal tool including a continuous and leak-free process gap through which the continuous workpiece travels, the process gap having a top wall, a bottom wall and side walls such that there exists an aspect ratio of 1/50 to 1/1000 between its height and width;
a moving mechanism to move the continuous workpiece through the process gap while keeping the back surface of the continuous workpiece in physical contact with the bottom wall while keeping a distance between the precursor layer and the top wall;
wherein the process gap further includes:
a top cold region with a first temperature range, a top buffer region, and a top hot region with a second temperature range associated with the top wall, such that the top buffer region is between the top cold region and the top hot region;
a bottom cold region, a bottom buffer region, and a bottom hot region associated with the bottom wall, such that the bottom buffer region is between the bottom cold region and the bottom hot region, so that a section of the continuous workpiece is subjected to a third temperature range as the section of the continuous workpiece travels over the bottom cold region and a fourth temperature range as the section of the continuous workpiece travels over the bottom hot region, and wherein the fourth temperature range is higher than the third temperature range; and
wherein the top buffer region and the bottom buffer region each includes a plurality of cavities within each of the top wall and the bottom wall that provide low thermal conductivity areas that together significantly inhibit transfer of thermal energy from the top hot region to the top cold region and from the bottom hot region to the bottom cold region, respectively, while still maintaining the process gap leak-free.

29. The apparatus of claim 28, wherein a part of the bottom buffer region is disposed below another part of the top hot region.

30. The apparatus of claim 28, wherein a part of the bottom cold region is disposed below another part of the top hot region.

31. The apparatus of claim 28, wherein a part of the bottom cold region is disposed below another part of the top buffer region.

32. The apparatus of claim 28, wherein the moving mechanism moves the continuous workpiece at a predetermined speed range through the process gap, and wherein, at the predetermined speed, the heating rate of the section of the continuous workpiece is at least 10° C./second as the section of the continuous workpiece passes through the bottom buffer region.

33. The apparatus of claim 28, wherein the cavities are holes cut in the portion of the top wall and the bottom wall.

34. The apparatus of claim 28 wherein the cavities are cut in a direction that is substantially perpendicular to the direction of travel for the continuous workpiece.

35. The apparatus of claim 34 wherein the cavities are substantially rectangular and are separated from one another by rectangular protrusions.

36. The apparatus of claim 35 wherein a width of each cavity is at least 2 mm.

37. The apparatus of claim 36, wherein a depth of the each cavity is 50% to 80% of the thickness of the top wall and the bottom wall.

38. The apparatus of claim 34 wherein the cavities are substantially cylindrical.
